(19) United States
(12) Patent Application Publication
(10) Pub. No.: US 2013/0234214 A1
(43) Pub. Date: Sep. 12, 2013

(54) SOLID-STATE IMAGING DEVICE AND METHOD OF MANUFACTURING THE SAME

(71) Applicant: Takeshi YOSHIDA, Yokohama-shi (JP)

(72) Inventor: Takeshi YOSHIDA, Yokohama-shi (JP)

(21) Appl. No.: 13/603,638

(22) Filed: Sep. 5, 2012

(30) Foreign Application Priority Data
Nov. 21, 2011 (JP) 2011-253710

(51) Int. Cl. H01L 31/02; H01L 31/18

(52) U.S. Cl. CPC H01L 31/02; H01L 31/18
USPC 257/239; 438/57

(57) ABSTRACT

According to one embodiment, a solid-state imaging device includes a semiconductor substrate, a photodiode provided in the semiconductor substrate and including a first conductivity type semiconductor layer, a shield layer provided on the photodiode, an upper portion or entirety of the shield layer being constituted of a second conductivity type semiconductor layer, and a transfer transistor provided on the semiconductor substrate to transfer charges stored in the photodiode to a floating diffusion region. An upper surface of the shield layer is higher than an upper surface of the semiconductor substrate.

### CROSS-REFERENCE TO RELATED APPLICATIONS

This application is based upon and claims the benefit of priority from Japanese Patent Application No. 2011-253710, filed Nov. 21, 2011, the entire contents of which are incorporated herein by reference.

### FIELD

Embodiments described herein relate generally to a solid-state imaging device and a method of manufacturing a solid-state imaging device.

### BACKGROUND

In recent years, the demand for camera components of mobile phones is increasing rapidly. In addition, CMOS sensors increasingly achieve higher image quality and higher performance and particularly, finer pixels to meet a desire for an increased number of pixels are strongly desired. With a desire for higher image quality, desires for reducing dark noise produced in pixels and defective pixels (called white spots) recognized as white points on a screen are increasing. This is called a defective mode in which the photodiode erroneously outputs a white signal because a dark current or leak current is caused by an interface state formed in an interface between a silicon substrate on a photodiode and an interlayer insulating film or by impurities such as metals trapped in an interface between a silicon substrate and an interlayer insulating film. By the occurrence of such the defective mode, the image quality is significantly degraded.

To prevent such degradation in image quality, a method of forming a photodiode in a slightly deep region of a silicon substrate so that the photodiode does not electrically come into contact with an interface between the silicon substrate and interlayer insulating film is used. Dark noise and white spots are reduced by this method and the image quality of a CMOS sensor is significantly improved.

A photodiode using this structure is in the form of being embedded in silicon and thus, the photodiode is called an embedded photodiode. Dark noise and white spots are reduced by using this structure, but a charge storage diffusion layer itself of the photodiode is formed, as “embedded” indicates, in a deeper position from the surface of the silicon substrate.

The charge storage diffusion layer of a photodiode serves as one of diffusion layer electrodes of a transfer transistor that transfers charges stored in the photodiode to a floating diffusion region and thus, if the photodiode is formed in a deeper position from the surface of the silicon substrate, the diffusion layer will be a transistor structure having an offset structure formed with a distance in a direction perpendicular to the interface of a gate insulating film. Thus, an increase in threshold voltage and a decrease in on-current are invited, leading to degraded transistor characteristics. As a result, charges stored in the charge storage diffusion layer of the photodiode are less likely to be output to the floating diffusion region even if the transfer transistor is turned on and thus, performance as an optical sensor is degraded.

### BRIEF DESCRIPTION OF THE DRAWINGS

FIG. 1 is a sectional view of a solid-state imaging device according to a first embodiment;

FIG. 2 is a sectional view showing a manufacturing process of the solid-state imaging device according to the first embodiment;

FIG. 3 is a sectional view showing the manufacturing process of the solid-state imaging device subsequent to FIG. 2;

FIG. 4 is a sectional view showing the manufacturing process of the solid-state imaging device subsequent to FIG. 3;

FIG. 5 is a sectional view showing the manufacturing process of the solid-state imaging device subsequent to FIG. 4;

FIG. 6 is a sectional view showing the manufacturing process of the solid-state imaging device subsequent to FIG. 5;

FIG. 7 is a sectional view showing the manufacturing process of the solid-state imaging device subsequent to FIG. 6;

FIG. 8 is a sectional view showing the manufacturing process of the solid-state imaging device subsequent to FIG. 7;

FIG. 9 is a sectional view showing the manufacturing process of the solid-state imaging device subsequent to FIG. 8;

FIG. 10 is a sectional view showing the manufacturing process of the solid-state imaging device subsequent to FIG. 9;

FIG. 11 is a sectional view showing another configuration example of a shield layer;

FIG. 12 is a sectional view showing the manufacturing process of the solid-state imaging device subsequent to FIG. 10;

FIG. 13 is a sectional view showing the manufacturing process of the solid-state imaging device subsequent to FIG. 12;

FIG. 14 is a sectional view of a solid-state imaging device according to a second embodiment;

FIG. 15 is a sectional view showing a manufacturing process of the solid-state imaging device according to the second embodiment;

FIG. 16 is a sectional view showing the manufacturing process of the solid-state imaging device subsequent to FIG. 15;

FIG. 17 is a sectional view showing the manufacturing process of the solid-state imaging device subsequent to FIG. 16;

FIG. 18 is a sectional view showing the manufacturing process of the solid-state imaging device subsequent to FIG. 17;

FIG. 19 is a sectional view showing the manufacturing process of the solid-state imaging device subsequent to FIG. 18;

FIG. 20 is a sectional view showing the manufacturing process of the solid-state imaging device subsequent to FIG. 19;

FIG. 21 is a sectional view showing another configuration example of the shield layer; and

FIG. 22 is a sectional view showing the manufacturing process of the solid-state imaging device subsequent to FIG. 20.

### DETAILED DESCRIPTION

In general, according to one embodiment, there is provided a solid-state imaging device comprising:

a semiconductor substrate;

a photodiode provided in the semiconductor substrate and including a first conductivity type semiconductor layer;

a shield layer provided on the photodiode, an upper portion or entirety of the shield layer being constituted of a second conductivity type semiconductor layer; and

a transfer transistor provided on the semiconductor substrate to transfer charges stored in the photodiode to a floating diffusion region,

wherein an upper surface of the shield layer is higher than an upper surface of the semiconductor substrate.

The embodiments will be described hereinafter with reference to the accompanying drawings. In the description which follows, the same or functionally equivalent elements are denoted by the same reference numerals, to thereby simplify the description.

### First Embodiment

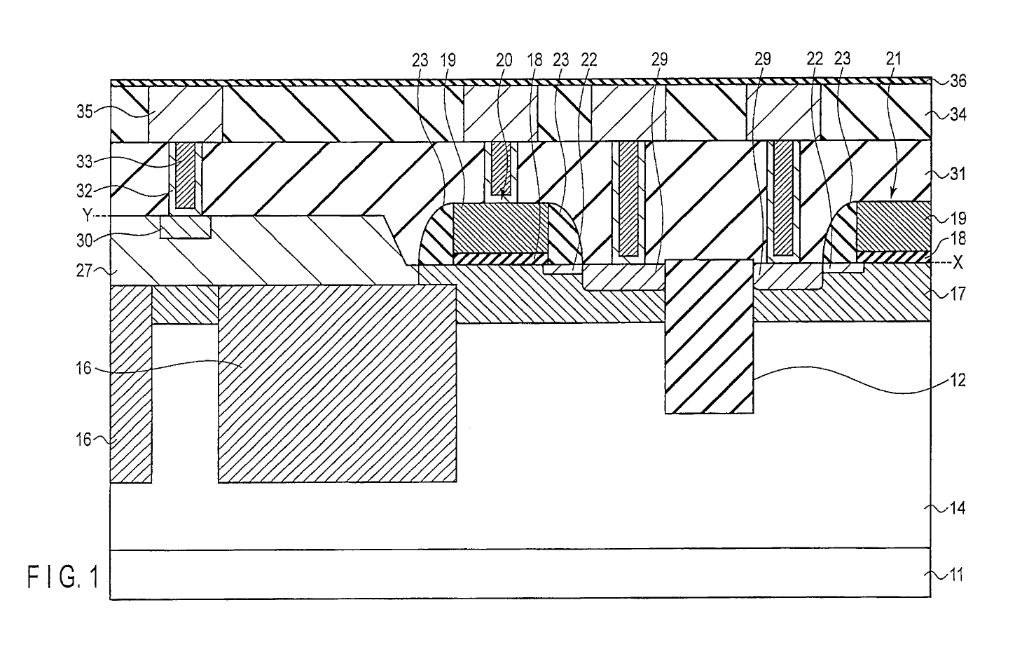

A solid-state imaging device according to the first embodiment is constituted of a CMOS sensor. FIG. 1 is a sectional view of a solid-state imaging device according to the first embodiment.

The solid-state imaging device includes a pixel array constituted of a plurality of pixels. Each pixel includes a photoelectric conversion element (photodiode) 16 that converts incident light into charges, a transfer transistor 20 that transfers charges stored in the photodiode 16 to a floating diffusion region 29, and an amplification transistor 21 that outputs the voltage of the floating diffusion region 29 as a signal level.

In FIG. 1, a symbol “X” indicates the position of an upper surface of a semiconductor substrate (for example, a silicon substrate) 11. An isolation layer 14 that electrically isolates the adjacent photodiodes 16 is provided in the silicon substrate 11. The isolation layer 14 is constituted of a P-type semiconductor layer. A channel region 17 for the transfer transistor 20 and the amplification transistor 21 is provided in a surface region of the silicon substrate 11. The channel region 17 is constituted of a P-type semiconductor region. When the transfer transistor 20 and the amplification transistor 21 are driven, channels of the transfer transistor 20 and the amplification transistor 21 are formed in the channel region 17.

The embedded photodiode 16 is provided in the silicon substrate 11. That is, the upper surface of the photodiode 16 is lower than an upper surface X of the silicon substrate 11. The photodiode 16 is constituted of an N-type semiconductor layer. A shield layer 27 constituted of a P-type semiconductor layer is provided on the photodiode 16. The shield layer 27 has a function to protect the photodiode 16 and particularly has a function to reduce dark noise and white spots (defective mode in which the photodiode erroneously outputs a white signal as a result of a dark current or leak current). An upper surface Y of the shield layer 27 is higher than the upper surface X of the silicon substrate 11.

With the above structure, while the shield layer 27 is provided on the photodiode 16, the photodiode 16 can be formed in a position close to the upper surface of the silicon substrate 11. The photodiode 16 functions also as a drain of the transfer transistor 20 and thus, the distance between a gate electrode 19 of the transfer transistor 20 and the photodiode 16 in a perpendicular direction can be shortened. Accordingly, the threshold voltage and the on-current of the transfer transistor 20 can be reduced so that transistor characteristics of the transfer transistor 20 can be improved.

(Manufacturing Method)

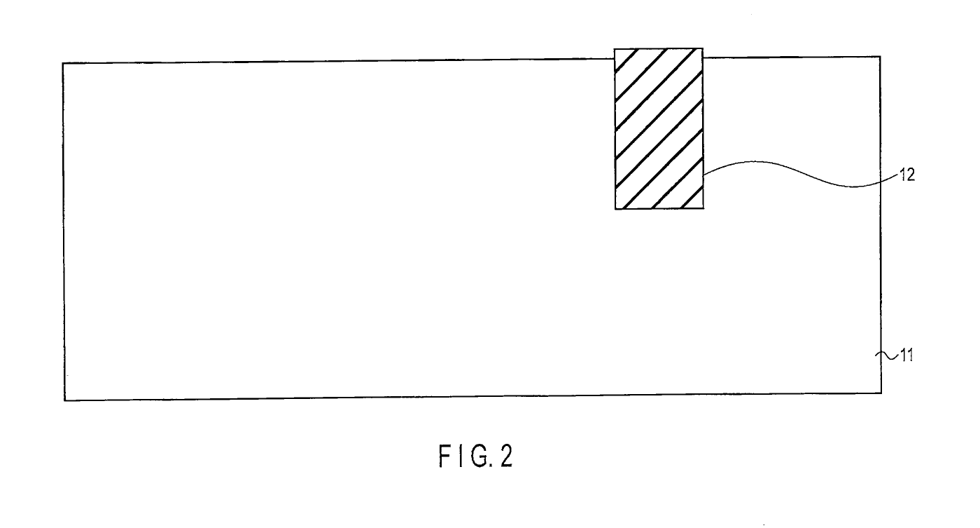

Next, the method of manufacturing a solid-state imaging device according to the first embodiment will be described with reference to the drawings. FIG. 2 is a sectional view showing a manufacturing process of the solid-state imaging device according to the first embodiment.

First, as the semiconductor substrate 11, for example, the P-type silicon substrate 11 which has the surface of a (100) plane and whose specific resistance is about 1 Ω·cm is prepared. An element isolation insulating layer 12 of the depth of about 3000 Å is formed in the silicon substrate 11. The element isolation insulating layer 12 is constituted of, for example, STI (Shallow Trench Isolation). Of the surface region of the silicon substrate 11, a region in which the element isolation insulating layer 12 is not formed becomes an element region in which semiconductor elements are formed.

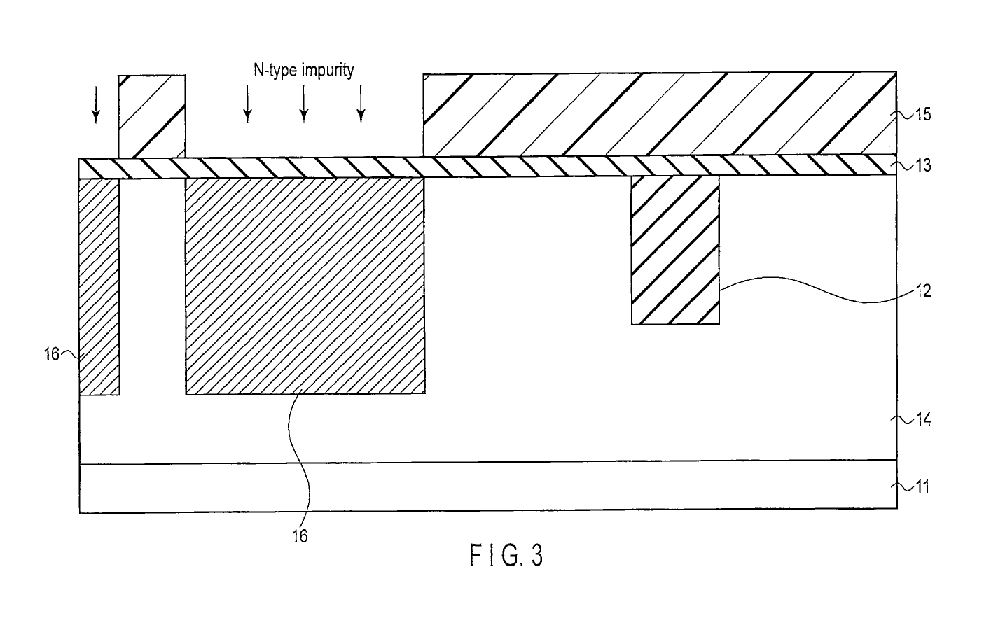

Subsequently, as shown in FIG. 3, a protection film 13 constituted of silicon oxide is formed on the upper surface of the silicon substrate 11 by, for example, oxidizing the surface region of the silicon substrate 11. Subsequently, the silicon substrate 11 is doped with a P-type impurity (for example, boron (B)) by ion implantation and annealed at high temperature of about 1000° C. for several minutes. Accordingly, the isolation layer 14 which electrically isolates the adjacent photodiodes and is constituted of a P-type semiconductor layer is formed. The isolation layer 14 needs to be formed up to a position deeper than that of a photodiode so that the photodiode to be formed later can be enclosed as a whole. Thus, the isolation layer 14 is formed by doping the silicon substrate with the P-type impurity at multi-stage acceleration voltages and further adjusting annealing conditions so that a sufficient diffusion distance of the P-type impurity is obtained.

Subsequently, a resist layer 15 is formed on the protection film 13 using the lithography method by covering a region other than the region in which the photodiode is formed. Subsequently, the isolation layer 14 is doped with an N-type impurity (for example, phosphor (P)) by ion implantation using the resist layer 15 as a mask. Then, after the resist layer 15 is removed, the silicon substrate is annealed to activate the N-type impurity. Accordingly, the photodiode 16 constituted of an N-type semiconductor region is formed in the isolation layer 14. The photodiode 16 is formed in such a way that, for example, the depth from the upper surface of the silicon substrate 11 is 0.1 μm or less.

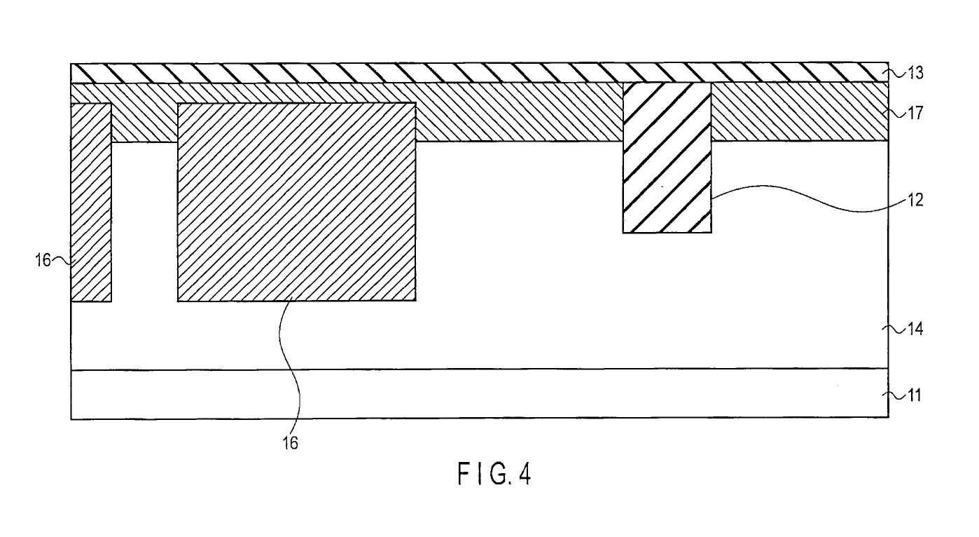

Subsequently, as shown in FIG. 4, the pixel region of the silicon substrate 11 is doped with a P-type impurity (for example, boron (B)) by ion implantation to form the channel region 17 for a MOSFET formed later in a surface region of the silicon substrate 11. The threshold voltage of the MOSFET can be controlled by controlling the impurity concentration of the channel region 17. The P-type semiconductor region (channel region 17) is also formed on the photodiode 16 by the above process. Then, the protection film 13 is etched.

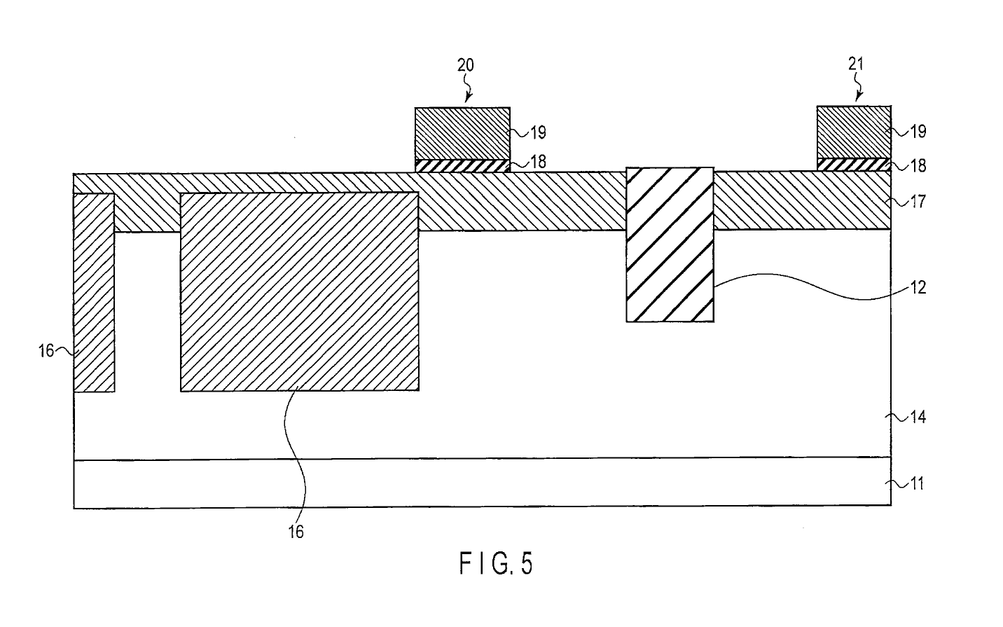

Subsequently, as shown in FIG. 5, a gate insulating film 18 is formed and a gate electrode material, for example, a polysilicon layer 19 is deposited on the gate insulating film 18 to a thickness of, for example, 1500 Å. Subsequently, the polysilicon layer 19 is doped with an N-type impurity (for example, phosphor (P)) by ion implantation to change the polysilicon layer 19 to an N-type conductive layer. Subsequently, the conductive layer 19 and the gate insulating film 18 are worked on to a desired shape by the lithography method and RIE (Reactive Ion Etching) method to form the gate electrode 19 of MOSFET (including the transfer transistor 20 and the amplification transistor 21) constituting each pixel. The transfer transistor 20 is a MOSFET to transfer signal charges stored in the photodiode 16 to a floating diffusion region. The amplification transistor 21 is a MOSFET to amplify and output the voltage of the floating diffusion region as a signal level.

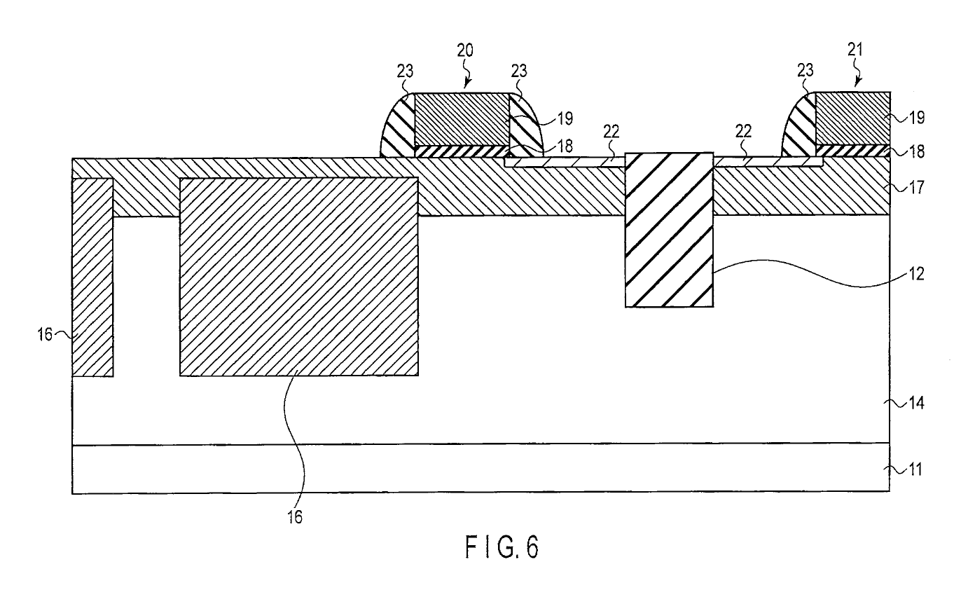

Subsequently, as shown in FIG. 6, after a resist layer (not shown) covering a region other than the region in which an LDD (Lightly Doped Drain) region of MOSFET is formed is formed on the silicon substrate 11 and the gate electrode 19 by the lithography method, the channel region 17 is doped with an N-type impurity (for example, phosphor (P)) by ion implantation. Then, after the resist layer is removed, the silicon substrate is annealed to activate the N-type impurity. Accordingly, an LDD region 22 for a source of the transfer transistor 20 and an LDD region 22 for a source and drain of the amplification transistor 21 are formed.

Subsequently, an insulating film (for example, silicon nitride) is deposited on the overall surface of the device and then the silicon nitride is etched back by using, for example, the RIE method. Accordingly, a sidewall 23 of the MOSFET is formed.

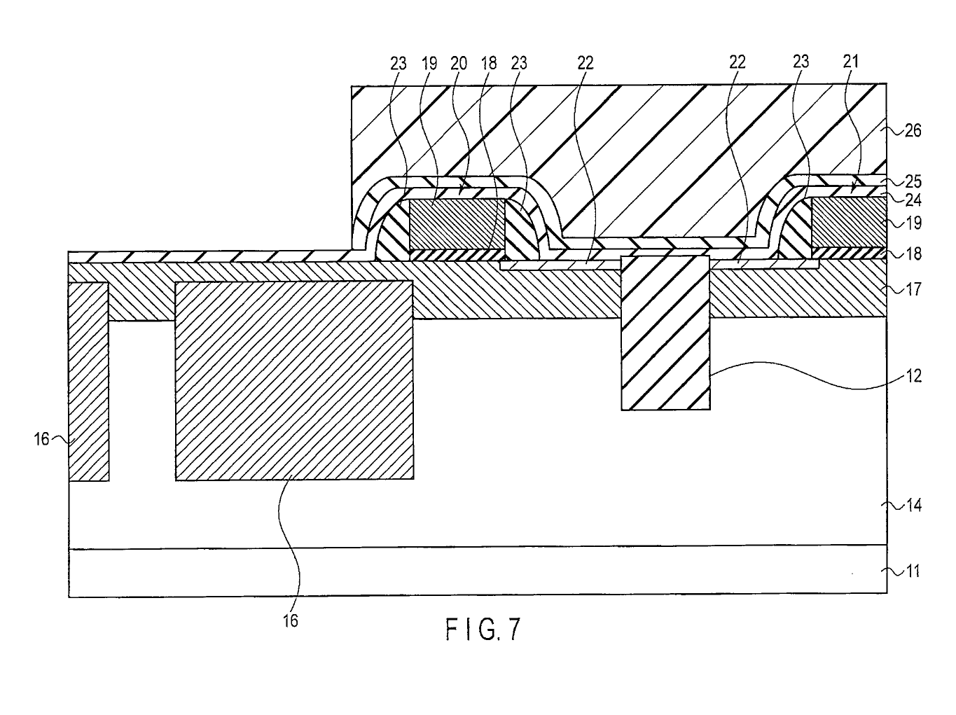

Subsequently, as shown in FIG. 7, a protection film 24 (for example, a TEOS (Tetra-Ethyl-Ortho-Silicate) film) is deposited on the overall surface of the device to a thickness of, for example, 5 nm and subsequently, a protection film 25 (for example, silicon nitride) is deposited on the TEOS film 24 to a thickness of, for example, 30 nm. Subsequently, a resist layer 26 to expose an area above the photodiode 16 is formed on the silicon nitride 25. Subsequently, the silicon nitride 25 is etched by using, for example, the RIE method using the resist layer 26 as a mask. Then, the resist layer 26 is removed.

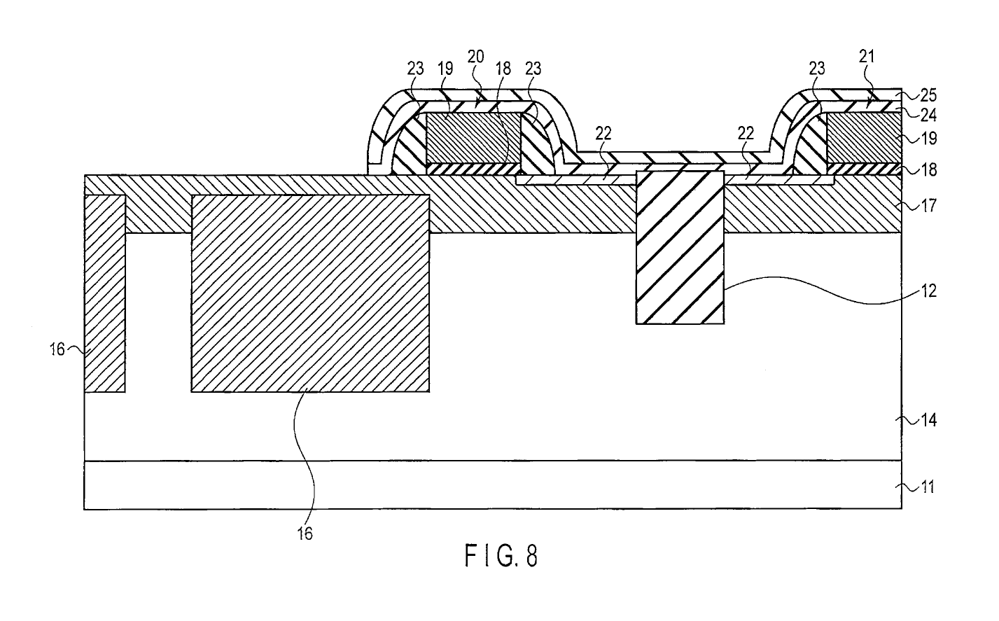

Subsequently, as shown in FIG. 8, the TEOS film 24 is wet-etched by using, for example, dilute fluoric acid using the silicon nitride 25 as a mask to expose the upper surface of the silicon substrate 11 above the photodiode 16.

In the present embodiment, the TEOS film 24 is formed on the silicon substrate 11. Then, wet etching using dilute fluoric acid is performed in the process in which the upper surface of the silicon substrate 11 is exposed. Thus, the upper surface of the silicon substrate 11 is not exposed to the RIE process when the upper surface of the silicon substrate 11 above the photodiode 16 is exposed and thus, the formation of an interface state or crystal defect in the silicon substrate 11 can be reduced. In place of the protection films 24, 25, resist layers may be formed. In such a case, the resist layers are formed into the same shape as that of the protection films 24, 25 by using the lithography method.

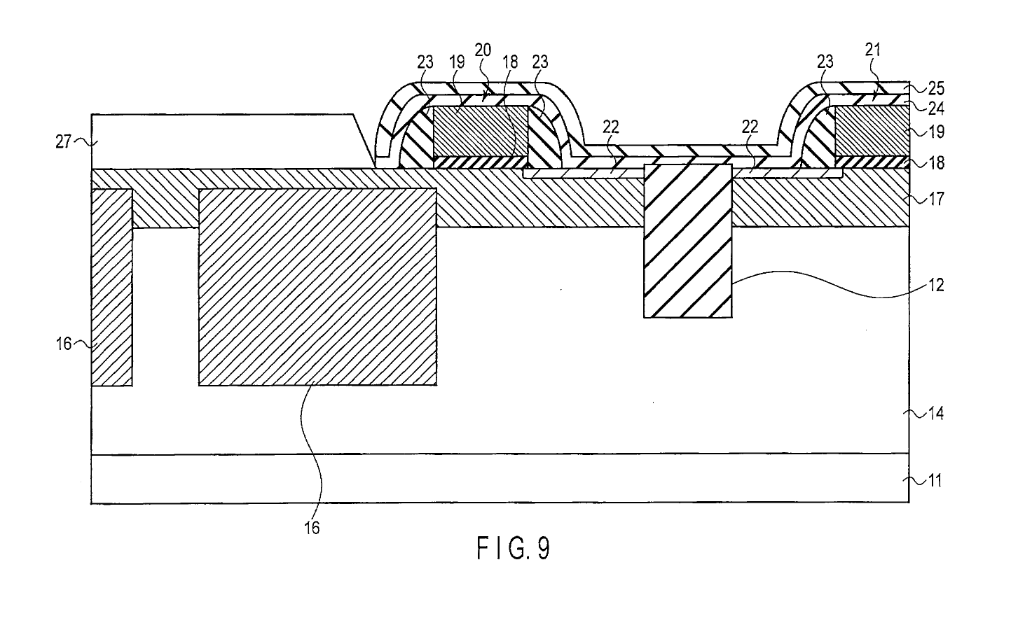

Subsequently, as shown in FIG. 9, a silicon layer 27 of about 1200 Å in thickness is epitaxially grown on the silicon substrate 11 above the photodiode 16 by applying a selective epitaxial growth method that allows an epitaxial layer to grow only on silicon to the overall surface of the device. In this case, there are only few crystal defects in the silicon substrate 11 and thus, an epitaxial layer having excellent crystallinity can be formed. Then, wet etching of only the silicon nitride 25 is performed by using, for example, high-temperature phosphoric acid (H₂PO₃) and then, wet etching of the TEOS film 24 is performed by using, for example, dilute fluoric acid.

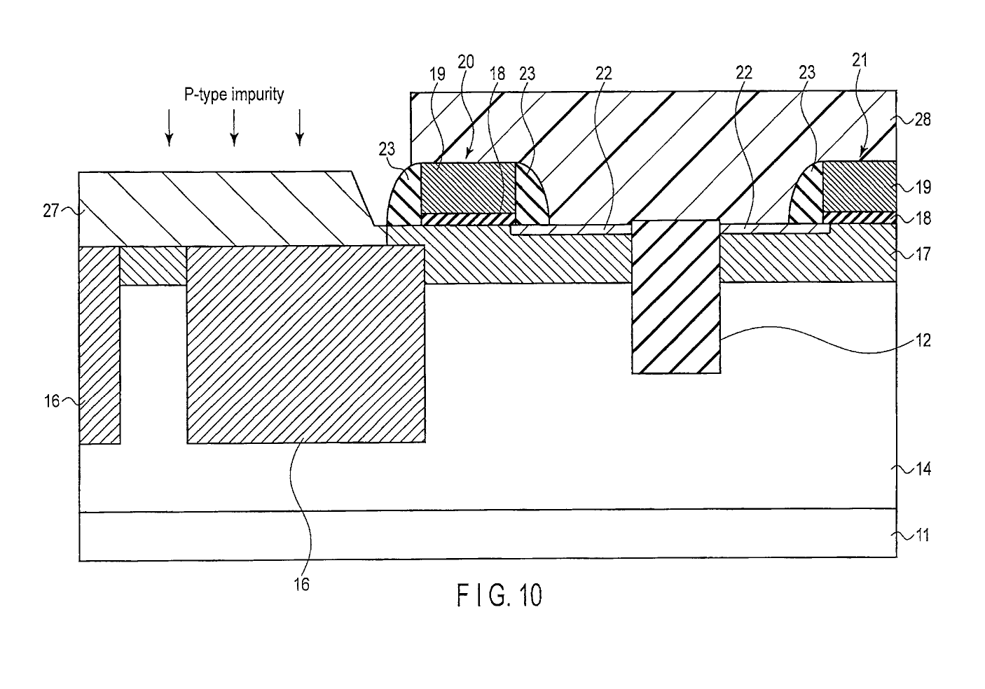

Subsequently, as shown in FIG. 10, a resist layer 28 exposing only the silicon layer (epitaxial layer) 27 is formed by using the lithography method. Subsequently, the silicon layer 27 is doped with a P-type impurity (for example, boron (B)) by ion implantation using the resist layer 28 as a mask. Then, after the resist layer 28 is removed, the silicon substrate is annealed to activate the P-type impurity. Accordingly, the shield layer 27 constituted of a P-type semiconductor layer is formed on the photodiode 16.

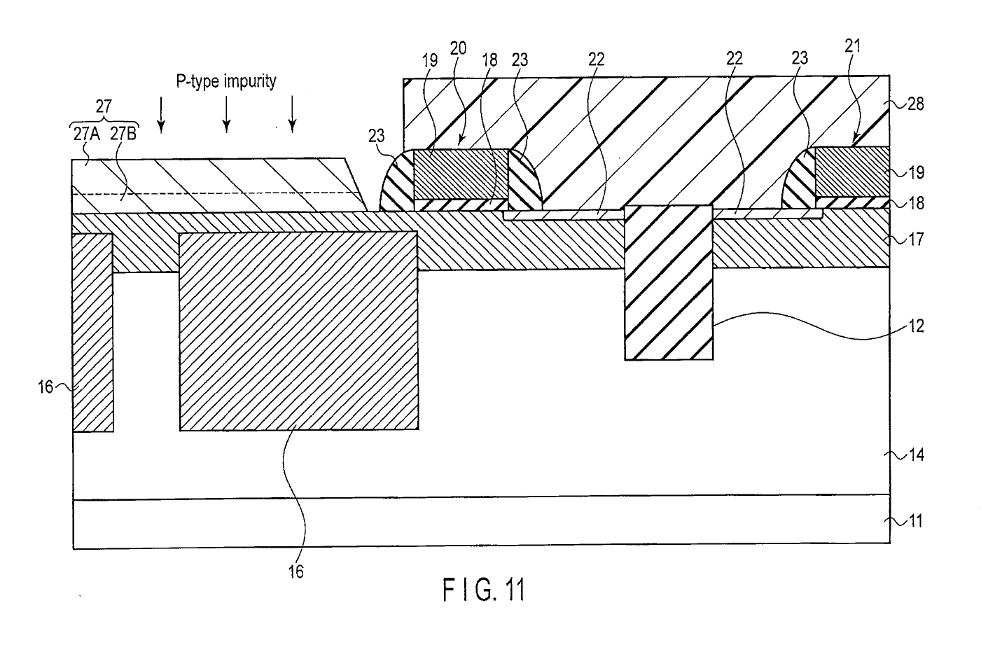

In FIG. 10, the whole shield layer 27 on the photodiode 16 is constituted of the P-type semiconductor layer, but the present embodiment is not limited to the above configuration. As shown in FIG. 11, depending on ion implantation conditions, the upper portion of the shield layer 27 may be constituted of a P-type semiconductor layer 27A by only the upper portion of the shield layer 27 being doped with a P-type impurity and the lower portion of the shield layer 27 may be constituted of an N-type semiconductor layer 27B. In such a case, a P-type semiconductor layer formed as the channel region 17 is provided between the photodiode 16 and the silicon layer 27B.

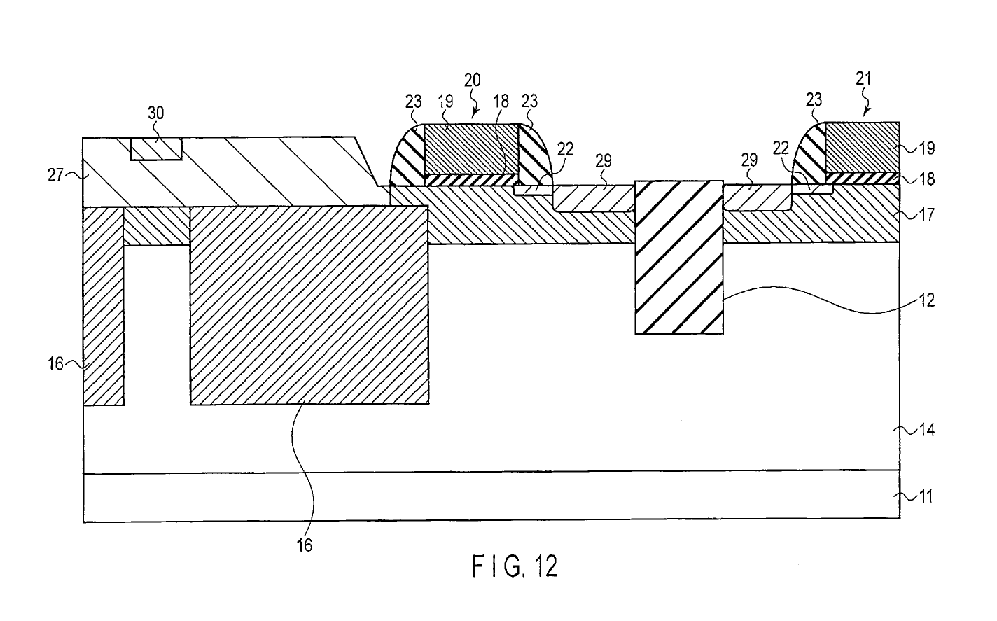

Subsequently, as shown in FIG. 12, after a resist layer (not shown) covering the shield layer 27 is formed by using the lithography method, the silicon substrate 11 is doped with a high-concentration N-type impurity (for example, phosphor (P)) by ion implantation using the resist layer as a mask. Then, after the resist layer is removed, the silicon substrate is annealed to activate the N-type impurity. Accordingly, an N⁺-type diffusion layer 29 having a higher impurity concentration than the LDD region 22 is formed as a source region and drain region of the MOSFET. The N⁺-type diffusion layer 29 includes the source region of the transfer transistor 20 and the source region and drain region of the amplification transistor 21.

The source region 29 of the transfer transistor 20 functions as a floating diffusion region. Signal charges stored in the photodiode 16 are transferred to the floating diffusion region by the transfer transistor 20. Then, the voltage of the floating diffusion region is output by the amplification transistor 21 as a signal level.

Subsequently, after a resist layer (not shown) having a desired shape is formed by using the lithography method, the shield layer 27 is doped with a high-concentration P-type impurity (for example, boron (B)) by ion implantation using the resist layer as a mask. Accordingly, a P⁺-type diffusion region 30 in ohmic and good contact with the shield layer 27 is formed in the surface region of the shield layer 27. The P⁺-type diffusion region 30 is formed in, for example, a boundary portion between photodiodes of adjacent pixels. Subsequently, after the resist layer is removed, the silicon substrate is annealed to activate the impurity. Accordingly, the foundation of the solid-state imaging device is completed.

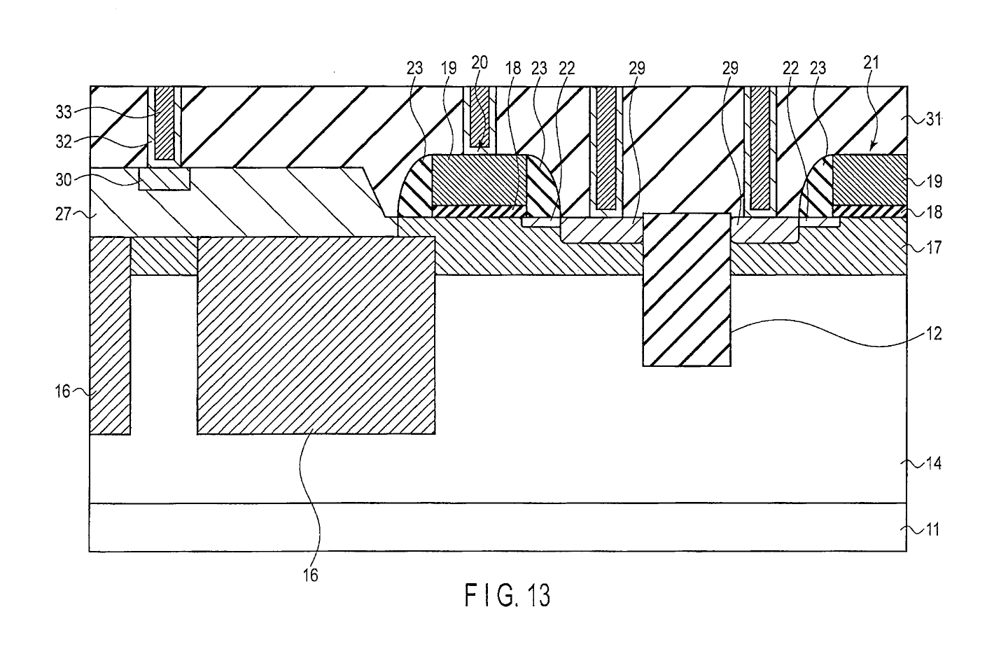

Subsequently, as shown in FIG. 13, a first interlayer insulating layer 31 (for example, a TEOS film) is deposited on the overall surface of the device and the interlayer insulating layer 31 is planarized by using the CMP (Chemical Mechanical Polishing) method. Subsequently, contact holes that expose the P⁺-type diffusion region 30 and electrodes (the gate, source, and drain) of the MOSFET are formed. Subsequently, a barrier film 32 including two layers of, for example, titanium (Ti)/titanium nitride (TiN) is formed in the contact hole by using a sputtering process. Subsequently, the contact hole is filled with a conductive material 33 (for example, tungsten (W)) by using, for example, the CVD (Chemical Vapor Deposition) method and excessive W and Ti/TiN in the upper layer are removed by using the CMP method. Accordingly, contact plugs 33 electrically connected to the P⁺-type diffusion region 30 and electrodes of the MOSFET are formed.

Subsequently, as shown in FIG. 1, a second interlayer insulating layer 34 (for example, a TEOS film) is deposited on the overall surface of the device and the second interlayer insulating layer 34 is planarized by using the CMP method. Subsequently, a wiring layer 35 (for example, a copper (Cu) wire) electrically connected to the contact plugs 33 is formed by using, for example, the damascene method. Subsequently, a protection film 36 (for example, silicon nitride) to inhibit the diffusion of copper (Cu) is deposited on the overall surface of the device. In this manner, a solid-state imaging device (more specifically, a pixel array of a solid-state imaging device) according to the first embodiment is completed.

(Effect)

In the first embodiment described above, a solid-state imaging device (CMOS sensor) includes the photodiode 16 provided in the silicon substrate 11 and having an N-type semiconductor layer, the shield layer 27 provided on the photodiode 16 and whose upper portion or entirety is constituted of a P-type semiconductor layer, and the transfer transistor 20 provided on the silicon substrate 11 to transfer charges stored in the photodiode 16 to a floating diffusion region. The upper surface Y of the shield layer 27 is higher than the upper surface X of the silicon substrate 11.

Therefore, according to the first embodiment, the embedded photodiode 16 can be formed close to the upper surface of the silicon substrate 11. Accordingly, the distance between the gate electrode 19 of the transfer transistor 20 and the photodiode 16 serving also as one diffusion layer of the transfer transistor 20 in a perpendicular direction can be shortened. As a result, the threshold voltage of the transfer transistor 20 can be lowered and also the on-current can be increased. Further, charges stored in the photodiode 16 can be read more correctly.

In addition, the formation of an interface state or crystal defect in the photodiode 16 can be reduced. Accordingly, noise of the photodiode 16 can be reduced. As a result, image quality of the CMOS sensor can be improved.

Moreover, in the process of forming the shield layer 27, the distance for diffusion of an impurity can be secured by making the thickness of the epitaxial layer thicker. Thus, the impurity concentration in the shield layer 27 and the photodiode 16 can be increased, improving flexibility in device design regarding the impurity concentration. Accordingly, if the impurity concentration of the shield layer 27 is increased, shielding properties can be increased so that noise and white spots resulting from an interface state can be reduced. If the impurity concentration of the photodiode 16 is increased, the amount of charges that can be stored in the photodiode 16 can be increased. As a result, the amount of electric signal when the photodiode 16 receive light can be increased, so that a high-performance CMO S sensor can be provided.

The present embodiment describes a case when the silicon substrate is the P type and the carrier storage layer of the photodiode 16 is the N type, but a similar effect can be achieved from a structure of pixels in which the conductivity type of semiconductor is reversed.

In the present embodiment, the semiconductor substrate and the epitaxial layer to form a shield layer are formed of silicon (Si), but a similar effect can also be achieved from other semiconductor materials such as germanium (Ge) and GaAs. Further, even if the semiconductor substrate and the epitaxial layer are formed of different semiconductor materials, for example, hetero-junction formation conditions such as forming an SiGe layer on a silicon substrate are provided, an effect similar to the above effect can be achieved without causing any problem if the substrate and the deposit film have a combination of lattice constants that does not fail and the shield layer is formed in such a way that a substrate interface portion in which an interface state is formed is enclosed.

### Second Embodiment

The second embodiment uses, as a semiconductor layer constituting a shield layer, the same semiconductor material as that of the semiconductor layer constituting a gate electrode of a MOSFET. Then, the semiconductor layer for the shield layer is formed at the same time as the process of forming the semiconductor layer for the gate electrode.

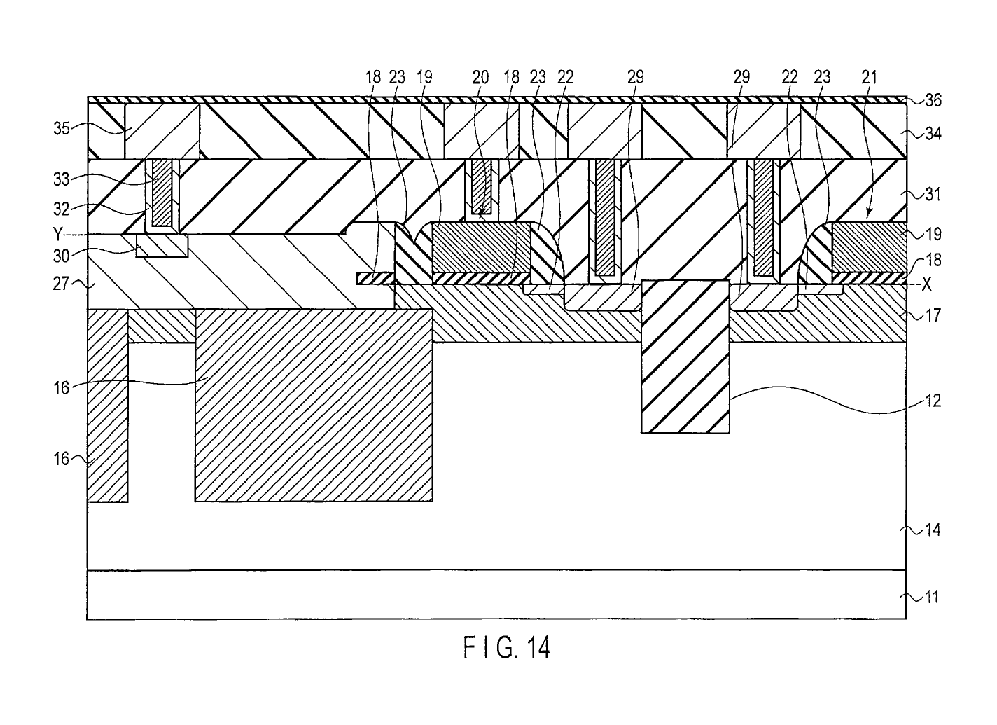

FIG. 14 is a sectional view of a solid-state imaging device according to the second embodiment. Like in the first embodiment, an embedded photodiode 16 is provided in a silicon substrate 11. That is, an upper surface of the photodiode 16 is lower than an upper surface X of the silicon substrate 11. A shield layer 27 is provided on the photodiode 16. An upper surface Y of the shield layer 27 is higher than the upper surface X of the silicon substrate 11. As the semiconductor layer constituting the shield layer 27, the same semiconductor material as that of the semiconductor layer constituting a gate electrode 19 of the MOSFET (including a transfer transistor 20 and an amplification transistor 21) is used.

Next, the method of manufacturing a solid-state imaging device according to the first embodiment will be described with reference to the drawings. The second embodiment undergoes the same manufacturing processes as those up to FIG. 4 in the first embodiment.

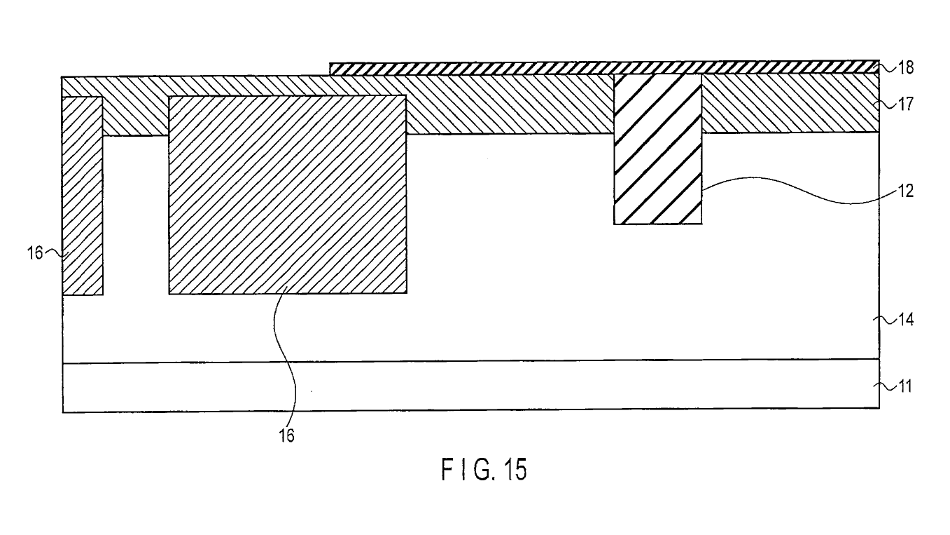

Subsequently, as shown in FIG. 15, after a protection film 13 is etched, a gate insulating film 18 is formed. Subsequently, after a resist layer (not shown) covering a region other than the region in which the shield layer 27 is formed by using the lithography method, the gate insulating film 18 is wet-etched by using, for example, dilute fluoric acid using the resist layer as a mask. Accordingly, the upper surface of the silicon substrate 11 in the region in which the shield layer 27 is formed is exposed. Then, the resist is removed.

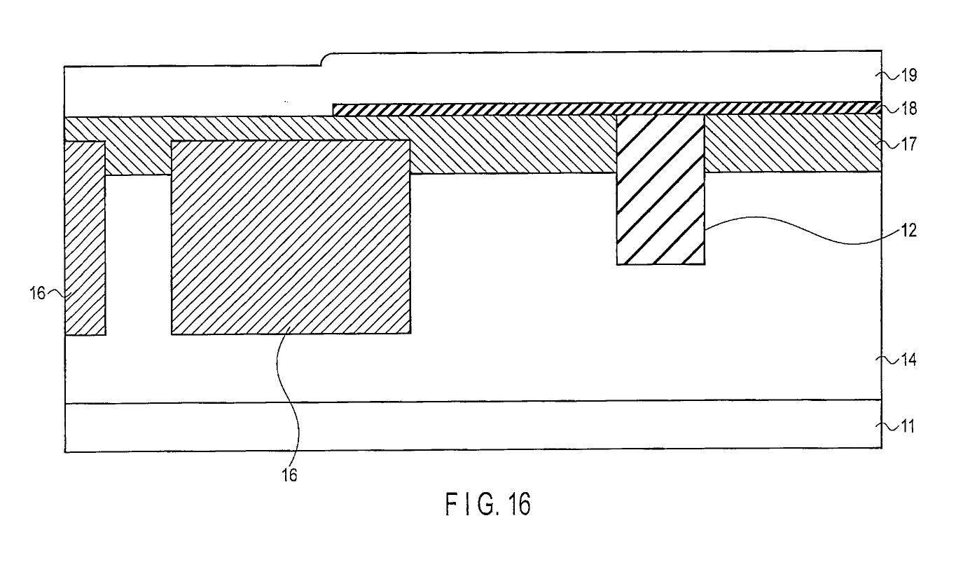

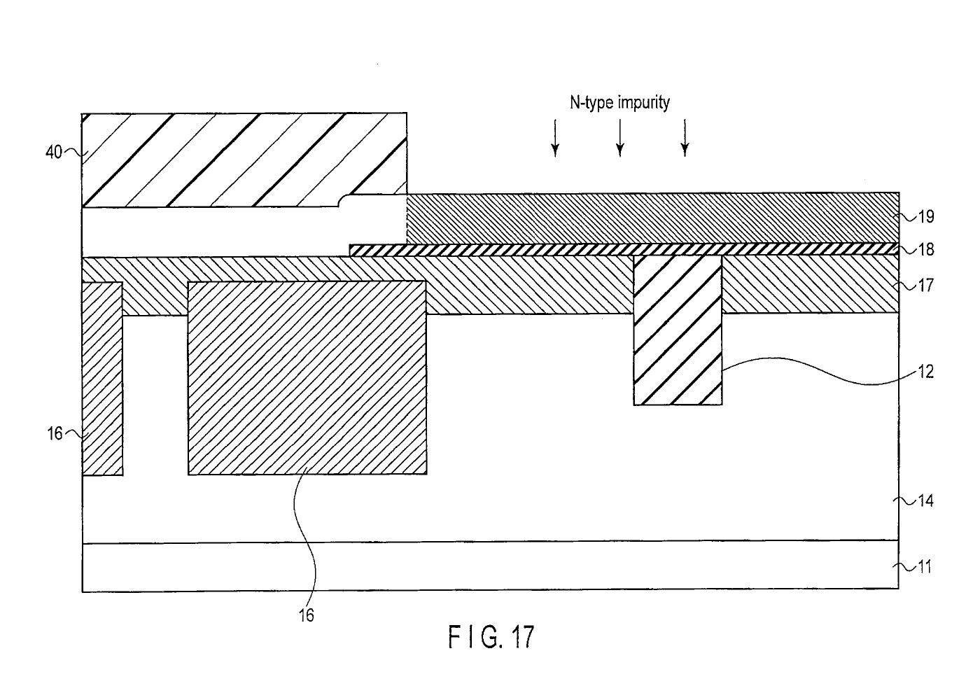

Subsequently, as shown in FIG. 16, a polysilicon layer 19 as the gate electrode material of the MOSFET is deposited on the overall surface of the device by using, for example, the CVD method to a thickness of, for example, 1500 Å. Subsequently, as shown in FIG. 17, a resist layer 40 covering the region in which the shield layer 27 is formed by using the lithography method. Subsequently, the polysilicon layer 19 is doped with an N-type impurity (for example, phosphor (P)) by ion implantation using the resist layer 40 as a mask, thereby the polysilicon layer 19 is partially changed to an N-type conductive layer. Then, the resist layer 40 is removed.

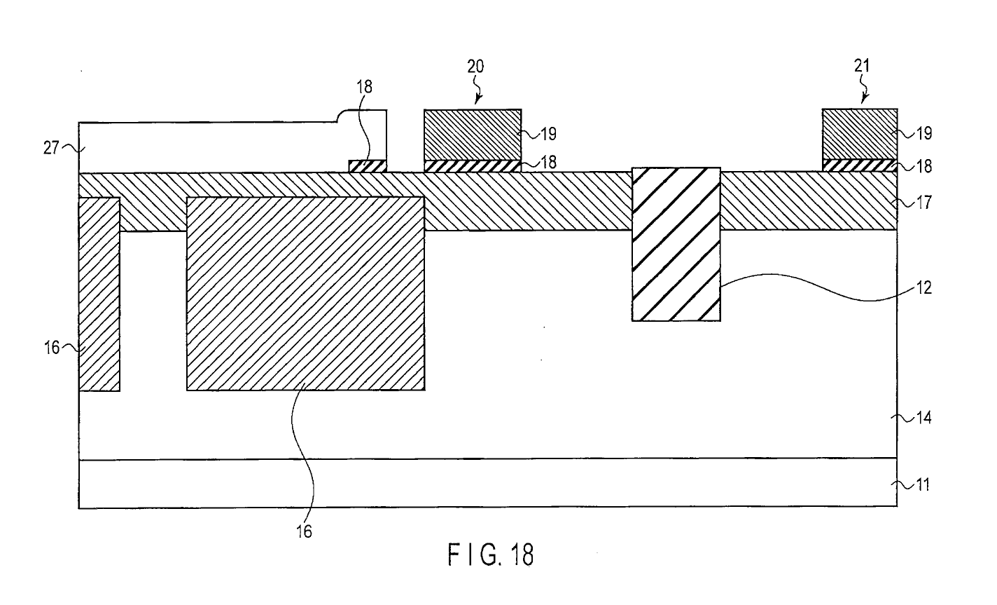

Subsequently, as shown in FIG. 18, a resist layer (not shown) covering a region in which gate electrodes of the MOSFETs constituting each pixel are formed and a region in which the shield layer 27 is formed is formed on the polysilicon layer 19 by using the lithography method and the polysilicon layer 19 is patterned by using, for example, the RIE method using the resist layer as a mask. Accordingly, the gate electrodes 19 of the MOSFETs (including the transfer transistor 20 and the amplification transistor 21) constituting each pixel are formed and also the polysilicon layer 19 to be a shield layer is formed.

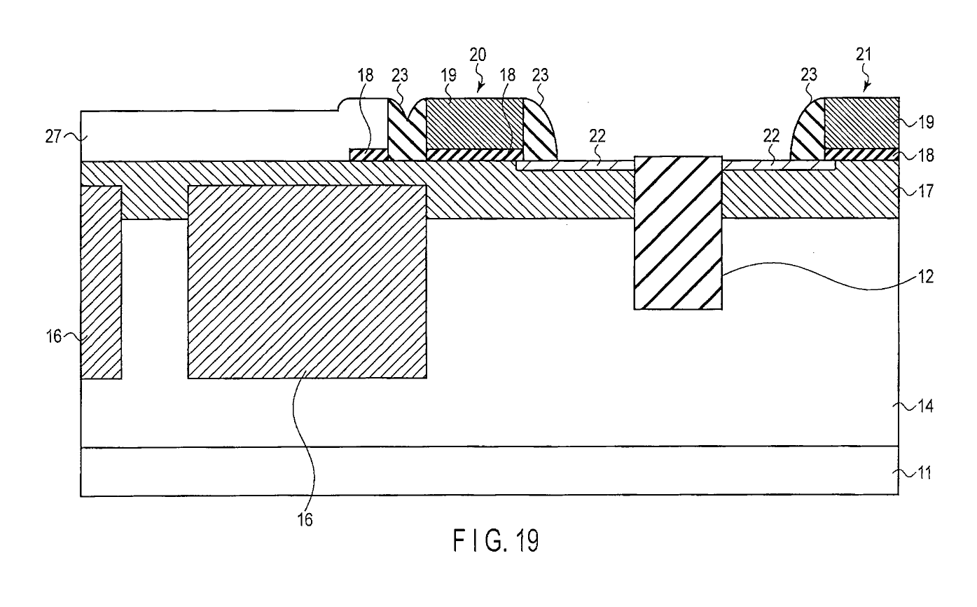

Subsequently, as shown in FIG. 19, after a resist layer (not shown) covering a region other than the region in which an LDD region of the MOSFET is formed is formed by using the lithography method, a channel region 17 is doped with an N-type impurity (for example, phosphor (P)) by ion implantation. Then, after the resist layer is removed, the silicon substrate is annealed to activate the N-type impurity. Accordingly, an LDD region 22 for the source of the transfer transistor 20 and an LDD region for the source and drain of the amplification transistor 21 are formed.

Subsequently, an insulating film (for example, a TEOS film) is deposited on the overall surface of the device and then the TEOS film is etched back by using, for example, the RIE method. Accordingly, a sidewall 23 of the MOSFET is formed. Also, a space between the gate electrode 19 of the transfer transistor 20 and the polysilicon layer 27 is filled with the sidewall 23.

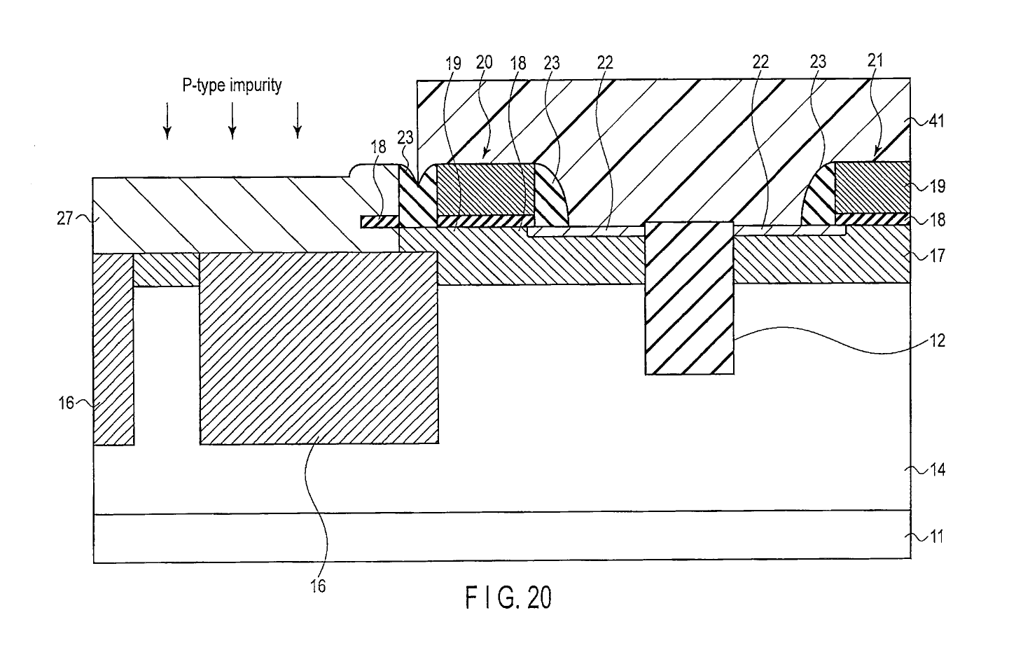

Subsequently, as shown in FIG. 20, a resist layer 41 exposing only the polysilicon layer 27 is formed by using the lithography method. Subsequently, the polysilicon layer 27 is doped with a P-type impurity (for example, boron (B)) by ion implantation using the resist layer 41 as a mask. Then, after the resist layer 41 is removed, the silicon substrate is annealed to activate the P-type impurity. Accordingly, the shield layer 27 constituted of the P-type semiconductor layer is formed on the photodiode 16.

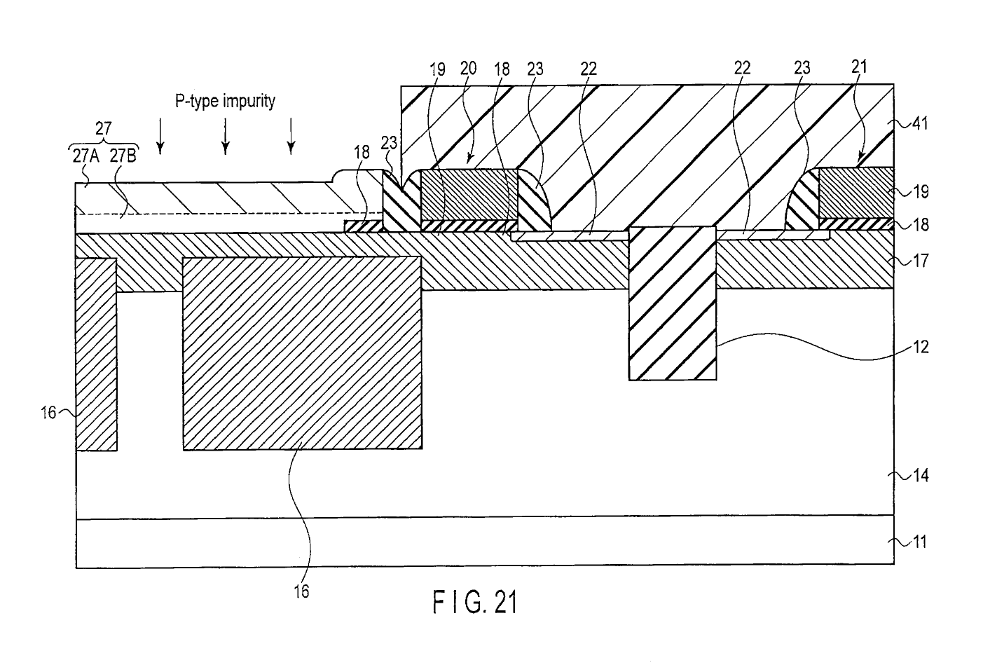

In FIG. 20, the whole shield layer 27 on the photodiode 16 is constituted of a P-type semiconductor layer, but the present embodiment is not limited to the above configuration. As shown in FIG. 21, depending on ion implantation conditions, the upper portion of the shield layer 27 may be constituted of a P-type semiconductor layer 27A by only the upper portion of the shield layer 27 being doped with a P-type impurity and the lower portion of the shield layer 27 may be constituted of an N-type semiconductor layer 27B. In such a case, a P-type semiconductor layer formed as the channel region 17 is provided between the photodiode 16 and the silicon layer 27B.

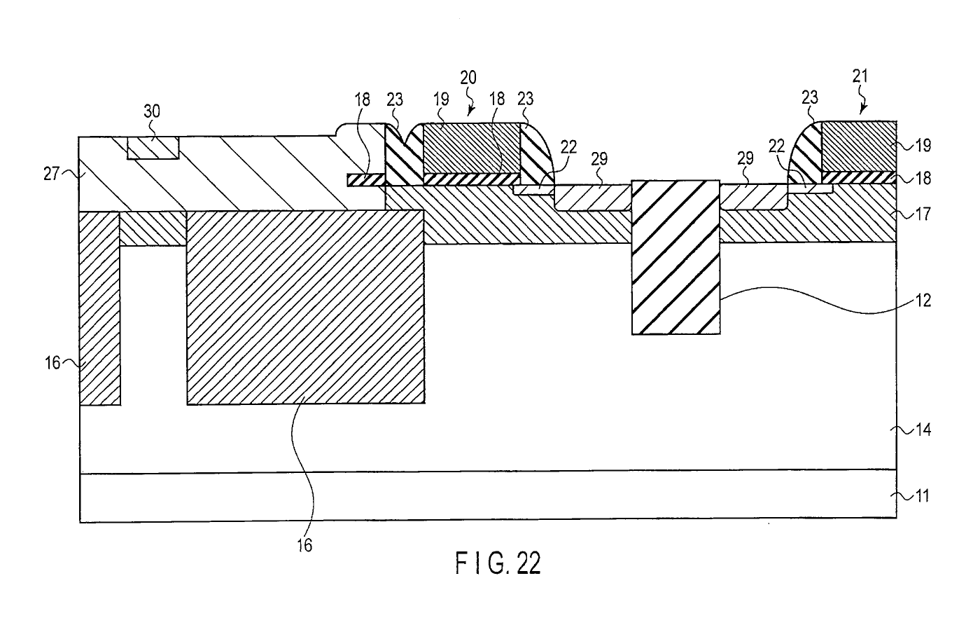

Subsequently, as shown in FIG. 22, after a resist layer (not shown) covering the shield layer 27 is formed by using the lithography method, the silicon substrate 11 is doped with a high-concentration N-type impurity (for example, phosphor (P)) by ion implantation using the resist layer as a mask. Then, the resist layer is removed. Accordingly, an N⁺-type diffusion layer 29 having a higher impurity concentration than the LDD region 22 is formed. The N⁺-type diffusion layer 29 includes the source region of the transfer transistor 20 and the source region and drain region of the amplification transistor 21.

Subsequently, after a resist layer (not shown) having a desired shape is formed by using the lithography method, the shield layer 27 is doped with a high-concentration P-type impurity (for example, boron (B)) by ion implantation using the resist layer as a mask. Accordingly, a P⁺-type diffusion region 30 in ohmic and good contact with the shield layer 27 is formed in the surface region of the shield layer 27. The P⁺-type diffusion region 30 is formed in, for example, a boundary portion between photodiodes of adjacent pixels. Subsequently, after the resist layer is removed, the silicon substrate is annealed to activate the impurity. Accordingly, the foundation of the solid-state imaging device is completed.

Subsequently, as shown in FIG. 14, a interlayer insulating layer 31, a barrier film 32, a contact plug. 33, a second interlayer insulating layer 34, wiring layer 35, and a protection film 36 are formed. The manufacturing processes of these are the same as those in the first embodiment. In this manner, a solid-state imaging device (more specifically, a pixel array of a solid-state imaging device) according to the second embodiment is completed.

(Effect)

According to the second embodiment described above, the upper surface of the shield layer 27 is made higher than the upper surface of the silicon substrate 11 and therefore, the embedded photodiode 16 can be formed close to the upper surface of the silicon substrate 11. Accordingly, the distance between the gate electrode 19 of the transfer transistor 20 and the photodiode 16 in a perpendicular direction can be shortened. As a result, the threshold voltage of the transfer transistor 20 can be lowered and also the on-current can be increased. Other effects are the same as those in the first embodiment.

In addition, the shield layer 27 can be formed by using the process of forming a gate electrode of a MOSFET. Accordingly, the number of manufacturing processes to form the shield layer 27 can be reduced and also manufacturing costs can be prevented from rising. Incidentally, the silicon layer in the shield layer 27 may be formed in a separate process from the process of forming a gate electrode.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solid-state imaging device comprising:
a semiconductor substrate;
a photodiode provided in the semiconductor substrate and including a first conductivity type semiconductor layer;
a shield layer provided on the photodiode, an upper portion or entirety of the shield layer being constituted of a second conductivity type semiconductor layer; and
a transfer transistor provided on the semiconductor substrate to transfer charges stored in the photodiode to a floating diffusion region,
wherein an upper surface of the shield layer is higher than an upper surface of the semiconductor substrate.

2. The device of claim 1, wherein the shield layer is constituted of an epitaxial layer.

3. The device of claim 1, wherein the shield layer is constituted of a same material as a material of a gate electrode of the transfer transistor.

4. The device of claim 1, wherein an upper surface of the photodiode is lower than the upper surface of the semiconductor substrate.

5. The device of claim 1, further comprising a diffusion region provided in a surface region of the shield layer and used for applying a voltage to the shield layer.

6. The device of claim 5, wherein the diffusion region is located between photodiodes included in adjacent pixels.

7. A method of manufacturing a solid-state imaging device, comprising:
forming a photodiode including a first conductivity type semiconductor layer in a semiconductor substrate;
forming an epitaxial layer on the semiconductor layer above the photodiode;
doping a second conductivity type impurity into the epitaxial layer to form a shield layer on the photodiode, an upper portion or entirety of the shield layer being constituted of a second conductivity type semiconductor layer; and
forming a transfer transistor on the semiconductor substrate to transfer charges stored in the photodiode to a floating diffusion region.

8. The method of claim 7, wherein an upper surface of the shield layer is higher than an upper surface of the semiconductor substrate.

9. The method of claim 7, wherein an upper surface of the photodiode is lower than an upper surface of the semiconductor substrate.

10. The method of claim 7, wherein the epitaxial layer is formed by selective growth in which a semiconductor layer grows only in a region in which the semiconductor substrate is exposed.

11. The method of claim 7, further comprising forming a protection film that prevents the epitaxial layer from growing in other regions of the semiconductor substrate than a region in which the epitaxial layer is formed.

12. The method of claim 7, further comprising forming a diffusion region for applying a voltage to the shield layer in a surface region of the shield layer,
wherein the diffusion region is located between photodiodes included in adjacent pixels.

13. A method of manufacturing a solid-state imaging device, comprising:
forming a photodiode including a first semiconductor layer of a first conductivity type in a semiconductor substrate;
forming a second semiconductor layer for a gate electrode of a transfer transistor on the semiconductor substrate, the transfer transistor transferring charges stored in the photodiode to a floating diffusion region;
forming a third semiconductor layer constituted of a same material as a material of the gate electrode on the semiconductor substrate above the photodiode;
doping a second conductivity type impurity into the third semiconductor layer to form a shield layer on the photodiode, an upper portion or entirety of the shield layer being constituted of a second conductivity type semiconductor layer; and
forming the transfer transistor on the semiconductor substrate.

14. The method of claim 13, wherein an upper surface of the shield layer is higher than an upper surface of the semiconductor substrate.

15. The method of claim 13, wherein an upper surface of the photodiode is lower than an upper surface of the semiconductor substrate.

16. The method of claim 13, wherein the second and third semiconductor layers are formed at the same time.

17. The method of claim 13, wherein the second and third semiconductor layers are formed by a CVD method.

18. The method of claim 13, wherein the second and third semiconductor layers are constituted of polysilicon.

19. The method of claim 13, further comprising forming a resist covering other regions of the semiconductor substrate than a region in which the third semiconductor layer is formed before doping the second conductivity type impurity into the third semiconductor layer.

20. The method of claim 13, further comprising forming a diffusion region for applying a voltage to the shield layer in a surface region of the shield layer,
wherein the diffusion region is located between photodiodes included in adjacent pixels.
